(19) United States
(12) Patent Application Publication
(10) Pub. No.: US 2005/0035370 A1
(43) Pub. Date: Feb. 17, 2005

(54) Semiconductor structure for a heterojunction bipolar transistor and a method of making same

(75) Inventor: Mary Chen, Oak Park, CA (US)

Correspondence Address: LADAS & PARRY, 5670 WILSHIRE BOULEVARD, SUITE 2100, LOS ANGELES, CA, 90036-5679, US

(73) Assignee: HRL LABORATORIES, LLC

(21) Appl. No.: 10/776,862

(22) Filed: Feb. 10, 2004

Related U.S. Application Data
(60) Provisional application No. 60/494,693, filed on Aug. 12, 2003.

(51) Int. Cl. H01L 31/0328

(52) U.S. Cl. 257/198

(57) ABSTRACT

An InP based NPN heterojunction bipolar transistor (HBT) having an emitter mesa; a base layer; an emitter ledge layer located above the base layer and below the emitter mesa, the emitter ledge layer having an intrinsic region located beneath the emitter mesa and an extrinsic region located outside the intrinsic region, the extrinsic region made of depleted semiconductor material; and base contacts formed within a portion of the extrinsic region of the emitter ledge layer and spaced at selected distances from the emitter mesa, wherein the base contacts electrically contact the base layer, and wherein the base contacts and the emitter ledge layer are disposed to cover an upper surface of the base layer so that there are no gaps in the emitter ledge layer between the base contacts and the emitter mesa to leave the upper surface of the base layer exposed.

### CROSS REFERENCE TO RELATED APPLICATIONS

The present application is related to and claims the benefit of co-pending U.S. Provisional Patent Application Ser. No. 60/494,693, filed on Aug. 12, 2003 and titled “A Semiconductor Structure For A Heterojunction Bipolar Transistor And A Method Of Making Same.” The disclosure of U.S. Provisional Patent Application No. 60/494,693 is incorporated herein by reference in its entirety.

### BACKGROUND

1. Field

The present invention relates to Indium Phosphide (InP) based heterojunction bipolar transistors (HBTs). More particularly, the present invention relates to InP-based HBTs passivated with a thin depleted emitter ledge.

2. Description of Related Art

InP-based HBTs are attractive for high-speed and low-power operation due to the inherent advantages of their material systems. These advantages result from excellent electron transport characteristics of their materials, such as high electron mobility, high peak electron drift velocity, and small energy band-gap of InGaAs. The small surface recombination velocities both in InP and InGaAs are also advantageous for fabricating submicron emitter devices for high-speed/high-density ICs without serious degradation of the current gain. In addition, InP-based.HBTs are highly attractive for applications to optoelectronic integrated circuits due to their capability of monolithic integration with long-wavelength optical devices.

However, fabrication techniques for InP-based HBTs are generally considered to be less developed than those for Gallium Arsenide (GaAs) based HBTs. Efforts in InP-based HBTs have been focused upon demonstrating high frequency performance of self-aligned HBTs, rather than reaching goals of higher yield and enhanced reliability. Therefore techniques for reaching the goals of higher yield and enhanced reliability remain new with respect to InP based HBTs.

One key concern with GaAs-based HBTs is exposure of the GaAs base surface layer, since an exposed base surface layer is known to lead to unnecessary additional base currents. One way in which this problem has been addressed in GaAs-based HBT technologies is the use of thin and depleted emitter ledge passivation. The use of thin and depleted emitter ledge passivation effectively reduces base surface recombination current near the emitter-base junction in GaAs-based HBT technologies. See, for example, W. Liu et al., “Critical Passivation Ledge Thickness in AlGaAs/GaAs Heterojunction Bipolar Transistors,” J. Vac. Sci. Technol. B 11(1), 1993, p. 6-9.

However, thin and depleted emitter ledge passivation techniques have not been applied to InP-based HBTs, because it is generally believed that, in comparison to GaAs-based HBTs, the depleted emitter ledge passivation effect may manifest less influence on current gain, due to the lower surface recombination velocity of InGaAs. However, InP-based NPN HBTs are not immune from external base surface recombination. In NPN HBTs, the base layer typically comprises p+ InGaAs. The Fermi level is pinned by high surface density states of InGaAs near 0.15 V below the conduction band of InGaAs, which has a band gap of 0.7V. For p+ InGaAs, the conduction band's bending in the band diagram shows a field for minority carriers (i.e., electrons) to recombine near the surface by diffusion through the bulk base layer. This recombination gives rise to the unnecessary and undesired base surface currents, and, especially, may be seen in scaled HBTs. Particularly, self-aligned HBTs may demonstrate a significant increase in the base surface recombination current near the emitter-base junction.

A primary focus for self-aligned HBTs is the reduction of base resistance. However, if the amount of overhang (which separates the base contact and the emitter mesa) is too small, the base surface and base contact recombination current may increase. On the other hand, if there is too much of an undercut of the emitter contact, the emitter resistance may increase. Many different, and often, quite complicated, processes may be used to control the fabrication of self-aligned InP-based HBTs, including dummy emitter formation, SiON side wall, and multiple coat and etch of polyimide to form emitter and base electrodes. See, for example, H. Shigematsu et al., IEEE Electron Device Letters, Vol. 16, No. 2, 1995, pp. 55-57. However, these processes for forming self-aligned HBTs, as indicated above, may be quite complicated and time consuming, leading to increased costs and decreased yields.

The structure and fabrication of prior art HBTs is disclosed in “InGaAs/InP Double-Heterostructure Bipolar Transistors With Near-Ideal β Versus Ic Characteristic” by R. N. Nottenburg et al., IEEE Electron Device Latter Vol. EDL-7, No. 11, 1986, pp.643-645. FIG. 1 illustrates an HBT 10 according to Nottenburg et al. The HBT 10 comprises an InP substrate layer 11, an InP buffer layer 13, an InP collector layer 15, an InGaAs base layer 17, an InP emitter layer 18, and an InGaAs emitter cap layer 19. The collector electrodes 12 comprise Au—Ge, the base electrode 14 comprises Au—Be, and the emitter electrode 16 comprises Au—Ge. Nottenburg et al. disclose HBTs with high emitter injection efficiency at very low collector current due to at least a factor of 100 smaller surface recombination current. The results were obtained without attempting junction edge passivation such as an emitter edge-thinning (i.e. emitter ledge). As can be seen in FIG. 1, there is a portion of the base layer 17 that is left uncovered between the base electrodes 14 and the emitter layer 18. The Nottenburg HBTs are of large emitter size: 16×40 to 44×100 μm². Since the emitter size is so large, external base surface recombination is not an important issue in the Nottenburg devices. However, the layer design and process may not be suitable for scaled InP-based HBTs for use at high frequencies.

An HBT with an emitter edge thinning design is disclosed in “Emitter edge-thinning effect on InGaAs/InP double-heterostructure-emitter bipolar transistor” by Yu-Huei Wu et al., Jpn. J. Appl. Phys. Vol. 34,1995, pp. 5908-5911. Wu et al. disclose a hetero-emitter composed of InP and InGaAs. FIG. 2 depicts an HBT 20 according to Wu et al. The Wu et al. HBT 20 comprises an n⁺ InP substrate 21, an n⁺ InP buffer layer 22, an n⁻ InP collector confinement layer 23, an n⁻ InGaAs collector 24, a p⁺InGaAs base 25, an n⁻ InGaAs emitter 26, an n InP emitter confinement layer 27, and an n⁺ InGaAs cap layer 28. The collector electrode 33 comprises AuGe or Ag, the base electrode 32 comprises AuZn, and the emitter electrode 31 comprises AuGe or Ag. The emitter 26 is thinned at its edge close to the base electrode 32 to form a ledge, but a portion of the base 25 is still left uncovered due to the gap between the emitter 26 and the base electrode 32. Further, formation of the thinned emitter edge may require additional and/or more complex fabrication steps than those used to form HBTs without a thinned emitter.

An HBT design using an emitter ledge is disclosed “Reliability implication of InGaP HBT emitter ledge dimension” by Even Yu et al. GaAs Reliability Workshop 2002, pp. 167-168. An HBT 40 according to Yu et al. is shown in FIG. 3. The HBT 40 comprises a collector 41, a base 43, an emitter mesa 45, an emitter ledge 47, an emitter contact 46, a base contact 44, and a collector contact 42. Yu shows effects of various lengths of the ledge 47 and gap between the ledge 47 and the base contact 44 to base current components. Some gaps result from unintentional misalignment in photolithography. The exposed gap between the ledge 47 and the base contact 44 cause less than 100% surface passivation.

Therefore, there is a need in the art for an HBT that provides for reduction of base surface recombination current and allows for use of conventional semiconductor fabrication processes, preferably without increasing base resistance. There is also a need to implement such features in InP-based HBTs that may also be scaled to higher frequencies. Finally, there is a need to provide such HBTs with enhanced manufacturability and reduced cost.

### SUMMARY

HBTs according to embodiments of the present invention have a thin and depleted emitter ledge layer portion that has no gaps between the emitter ledge portion and the base contacts, thus providing for 100% surface passivation of the surface of the base layer. Ledge thickness is known to be critical in making a ledge work properly for surface passivation. See, for example, W. Liu et al., “Parasitic Conduction Current in the Passivation Ledge of AlGaAs/GaAs Heterojunction Bipolar Transistors,” Solid State Electronics, Vol. 35, No. 7, pp. 891-895, 1992. Therefore, embodiments of the present invention provide for methods to control the thickness of the ledge layer and devices that have ledge layers with controlled thicknesses. The separation of the base contacts of the HBT and the emitter mesa is controlled by the length of the emitter ledge. The length of the depleted ledge portion is easily controlled by photo lithographic techniques well known in the art that can bring the base contacts as close to the emitter mesa as needed.

HBTs according to some embodiments of the present invention have reduced base surface recombination current near the emitter-base junction, which provides for improved current gain. Such a feature may be particularly important to scaled HBTs, because extrinsic base surface recombination current often dominates the total base current. It is known that surface-recombination mechanisms can modify the base-region transport efficiency. See, for example, D. P. Kennedy, Solid-State Electronics, Vol. 3, 1961, pp. 215-225. The length of the fully depleted ledge portion according to embodiments of the present invention can be designed to reduce the base contact recombination current. HBTs according to embodiments of the present invention should then have DC characterizations that are more ideal without sacrificing RF performance.

As noted above, the thickness of the depleted emitter ledge portion may be critical for making the ledge portion work properly for surface passivation. However, according to embodiments of the present invention, the emitter ledge thickness can be controlled according to well known semiconductor fabrication techniques. The quality of the ledge can be monitored by effective area ratio and CV measurements. See, for example, P. J. Zampardi et al., “Methods for Monitoring Passivation Ledges in a Manufacturing Environment,” GaAs Mantech Conference, 2002, pp. 225-228.

The manufacturability of InP-based HBTs according to embodiments of the present invention will be enhanced because the thickness and length of the emitter ledge can be controlled by conventional processes. Further, embodiments of the present invention provide for good contact between the base electrodes and the base layer.

The emitter ledge layer according to embodiments of the present invention also protects the base layer from being attacked in sequential process steps. Therefore it can be applied to both InP based SHBT (single hetero-junction HBT) and DHBTs (double hetero-junction HBTs) including InP/GaAsSb/InP DHBTs.

Essentially, the emitter ledge layer and the base contacts in embodiments according to the present invention serve to seal the base layer. Hence, the emitter ledge layer passivates the surface of the base layer to reduce base contact recombination current near the emitter-base junction.

Embodiments of the present invention may provide more planar device structure and potential for new interconnect design. Thus, embodiments of the present invention device may enhance large scale circuit integration for use in applications, such as radar and communication systems.

A first embodiment according to the present invention is a semiconductor structure comprising: an emitter mesa; a base layer; an emitter ledge layer located above the base layer and below the emitter mesa, the emitter ledge layer having an intrinsic region located beneath the emitter mesa and an extrinsic region located outside the intrinsic region, the extrinsic region comprising depleted semiconductor material; and one or more base contacts located within an etched portion of the extrinsic region of the emitter ledge layer and spaced at selected distances from the emitter mesa, wherein the one or more base contacts electrically contact the base layer, where the base contacts and the emitter ledge layer are disposed to cover an upper surface of the base layer so that there are no gaps in the emitter ledge layer between the one or more base contacts and the emitter mesa to leave the upper surface of the base layer exposed.

Another embodiment according to the present invention is a method for fabricating a heterojunction bipolar transistor (HBT) comprising: providing a substrate; forming a collector layer and a base layer for the HBT on the substrate; forming an emitter ledge layer above the base layer; forming an emitter mesa region above the emitter ledge layer; and forming one or more base contacts in the emitter ledge layer at selected distances from the emitter mesa, the one or more base contacts in electrical contact with the base layer, where the emitter ledge layer has an intrinsic region located beneath the emitter mesa and an extrinsic region located outside the intrinsic region and the extrinsic region comprises depleted semiconductor material and where the one or more base contacts are formed in the extrinsic region and one or more base contacts and the emitter ledge layer are formed so that there are no gaps in the extrinsic region of the emitter ledge layer between the one or more base contacts and the emitter mesa to leave an upper surface of the base layer exposed.

Still another embodiment of the present invention is a semiconductor structure comprising an InP-based NPN heterojunction bipolar transistor (HBT) wherein the InP-based NPN HBT has a fully depleted emitter ledge layer region disposed between one or more base contacts and an emitter mesa to 100% or nearly 100% passivate an upper surface of a base layer of the InP-based NPN HBT.

### BRIEF DESCRIPTION OF THE DRAWINGS

FIG. 1 (prior art) shows the structure of a first prior art HBT.

FIG. 2 (prior art) shows the structure of a second prior art HBT.

FIG. 3 (prior art) shows the structure of a third prior art HBT.

FIG. 4A shows a schematic of layers of an HBT according to one embodiment of the present invention.

FIG. 4B shows a schematic of layers of an HBT according to another embodiment of the present invention.

FIGS. 5A-5D show a method according to the present invention used to fabricate the HBT depicted in FIG. 4A.

FIGS. 6A-6C show a method according to the present invention used to fabricate larger base contacts.

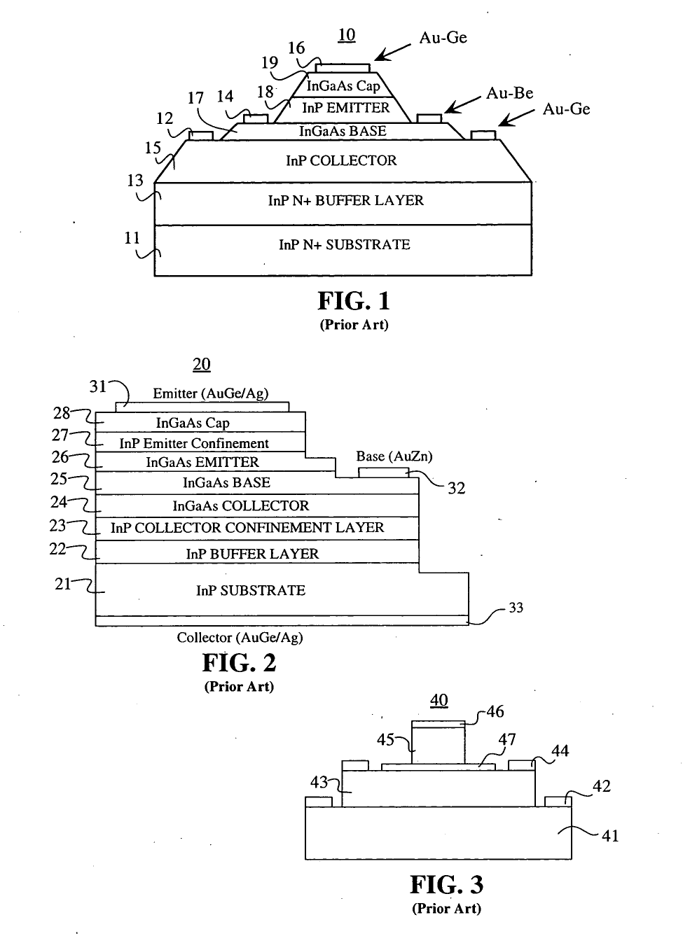

### DETAILED DESCRIPTION

Embodiments of the present invention will now be described more fully hereinafter with reference to the accompanying drawings. This invention may be embodied in many different forms and should not be construed as limited to the embodiments set forth herein. In the drawings, the thicknesses of layers and regions are exaggerated for clarity.

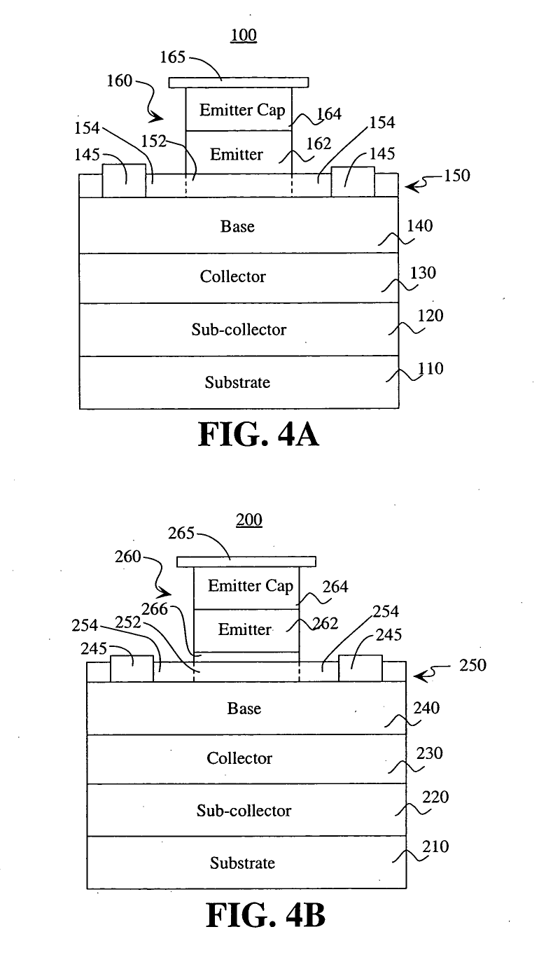

FIG. 4A shows the layers of an HBT 100 and its emitter and base contacts 145, 165 according to an embodiment of the present invention. The HBT 100 comprises a substrate layer 110, a sub-collector layer 120 disposed above the substrate layer 110, a collector layer 130 disposed above the sub-collector layer 120, a base layer 140 disposed above the collector layer 130, an emitter ledge layer 150 disposed above the base layer 140, and an emitter mesa 160 disposed above the emitter ledge layer 150. The emitter ledge layer 150 comprises an intrinsic region 152 that is located beneath the emitter mesa 160 and extrinsic region 154 that is located outside that portion of the emitter ledge layer 150 that is beneath the emitter mesa 160. In operation, the intrinsic region 152 of the emitter ledge layer 150 is considered to be part of the emitter of the HBT 100. The emitter mesa 160 preferably comprises an emitter layer 162, an emitter cap layer 164 and an emitter contact 165. Base contacts 145 are disposed in gaps in the extrinsic region 154 of the emitter ledge layer 150. The extrinsic region 154 of the emitter ledge layer 150 is preferably disposed to cover the base layer 140 so that the surface of the base layer is 100% or nearly 100% passivated. Therefore, the base contacts 145 are preferably in physical contact with both the base layer 140 and the extrinsic region 154 of the emitter ledge layer 150.

For an InP-based HBT, the emitter mesa 160 may comprise an InAlAs emitter mesa. For an InAlAs emitter mesa, the emitter cap layer 164 preferably comprises a n⁺ InGaAs layer and a n⁺ AlInAs layer, the emitter layer 162 preferably comprises n⁻ AlInAs, and the emitter ledge layer 150 comprises n⁻ InP. The extrinsic region 154 of the emitter ledge layer 150 should be fully depleted to reduce the base surface recombination current, as described below. There may also be a thin spacer layer (not shown in FIG. 4A) between the emitter ledge layer 150 and the base layer 140 comprising p InGaAs or p GaAsSb, depending on the base layer 140 dopant. For an InP-based single heterojunction bipolar transistor (SHBT), the base layer 140 preferably comprises p⁺ InGaAs and the collector layer 130 preferably comprises n⁻ InGaAs. For an InP-based double heterojunction bipolar transistor (DHBT), the base layer 140 preferably comprises p⁺ GaAsSb and the collector layer 130 comprises n⁻ InP. Alternatively, for a DHBT according to an embodiment of the present invention, the base layer 140 comprises p⁺ InGaAs and the collector layer 130 comprises n⁻ InP with a quaternary or a chirped super-lattice layer (not shown in FIG. 4A) disposed between the base layer 140 and the collector layer 130. For both the SHBT and the DHBT, the sub-collector layer 120 may comprise n⁺ InP or n⁺ InGaAs or a combination of n⁺ InP and n⁺ InGaAs.

The emitter contact 165 may comprise a metal or other material known in the art for use in contacting the emitter portion of an HBT. The base contacts 145 preferably comprise layers of Platinum, Titanium, Platinum, and Gold (Pt/Ti/Pt/Au). Such a composition for base contacts 145 is known for use with GaAs-based HBTs, InP/InGaAs-based HBTs, and InP/GaAsSb-based HBTs. See, for example, S. Yamahata et al., GaAs IC Symposium, 1994, pp. 345-348 and C. R. Bolognesi et al., GaAs IC Symposium, 1999, pp. 63-66.

An HBT 200 with an emitter mesa 260 for an InP emitter is shown in FIG. 4B. The substrate layer 210, the sub-collector layer 220, the collector layer 230, the base layer 240, and the emitter ledge layer 250 have a similar structure and composition to the layers of the HBT 100 depicted in FIG. 4A. The emitter and base contacts 265, 245 also preferably comprise the materials as discussed above for the HBT 100 depicted in FIG. 4A. The emitter mesa 260 comprises an emitter cap layer 264, an emitter layer 262, and an etch stop layer 266. The emitter cap layer 264 preferably comprises a layer of n⁺ InGaAs and a layer of n⁺ InP. The emitter layer 262 preferably comprises n⁻ InP. The etch stop layer 266 preferably comprises a thin layer (approximately 50 Å) of Al_{0.24}Ga_{0.23}In_{0.53}As. For the HBT depicted in FIG. 4B, the emitter ledge layer 250 again comprises a thin layer n⁻ InP. The emitter ledge layer 250 also consists of an intrinsic region 252 located beneath the emitter mesa 260 and an extrinsic region 254 that is located outside that portion of the emitter ledge layer 250 that is beneath the emitter mesa 260. The extrinsic region of the emitter ledge layer 250 should be fully depleted, as described below. The extrinsic region 254 of the emitter ledge layer 250 also preferably covers the base layer 240 so that the surface of the base layer 240 is 100% or nearly 100% passivated.

In preferred embodiments of the present invention, the structure of the emitter ledge layer 150, 250 is extremely important. As noted above, the extrinsic regions 154, 254 of the emitter ledge layer 150, 250 preferably comprise material that is fully depleted, so that those regions 154, 254 can effectively serve as a surface passivation layer. Otherwise, parasitic conduction current in the emitter ledge layer 150, 250 will increase base contact recombination current. This phenomena for GaAs-based HBTs is described in additional detail in W. Liu et al., “Parasitic Conduction Current in the Passivation Ledge of AlGaAs/GaAs Heterojunction Bipolar Transistors,” Solid State Electronics, Vol. 35, No. 7, 1992, pp. 891-895.

Preferably the emitter ledge layer 150, 250 is fabricated so that the surface depletion region (at the top of the extrinsic region 154, 254 of the emitter ledge layer 150, 250) and the p/n junction depletion region (at the bottom of the extrinsic region 154, 254 of the emitter ledge layer 150, 250) essentially touch each other, i.e., no undepleted part in the emitter ledge layer 150, 250 exists in the extrinsic region 154, 254 of the emitter ledge layer 150, 250. The depletion from the p/n junction depletion region thickness varies with V_{be} during operation and decreases under forward bias. The surface depletion depth may be affected by possible doping level shifts and/or growth rate shift (or miscalibration of growth rate) during the growth of the emitter ledge layer 150, 250, and also affected by dielectric layer passivation on top of the emitter ledge layer 150, 250, which is typical for HBT fabrication. Therefore, the thickness of the emitter ledge layer 150, 250 is preferably less than surface depletion depth. Thus, the upper limit of the emitter ledge layer 150, 250 thickness is mainly set by the desired ledge performance. Since the intrinsic region 152, 252 of the emitter ledge layer 150, 250 may be considered to be part of the emitter, the lower limit of the emitter ledge layer 150, 250 thickness may depend on such factors as beta, emitter/base breakdown voltage, emitter/base capacitance and reliability. In preferred embodiments according to the present invention, the emitter ledge layer 150, 250 will have a thickness ranging from 200 Å to 500 Å and generally on the order of a few hundred angstroms. Thus, due to its thinness, the emitter ledge layer 150, 250 should be protected in later processing of the HBT.

The doping levels for n⁻ InAlAs or n⁻ InP in the emitter layers 162, 262 discussed above are based on requirements for device and circuit applications, including collector current, emitter resistance and emitter-base capacitance. The doping levels may range from 10¹⁷/cm³ to 10¹⁸/cm³ or other levels or ranges that may be used to achieve the desired characteristics.

The thickness of the emitter layer 162, 262 should be thick enough so that back-injection of holes into the emitter is negligible. Preferably, the total thickness of the emitter ledge 150, 250 and the emitter layer 162, 262 should be approximately 1000 Å.

In an embodiment of the HBT 100 depicted in FIG. 4A, the emitter cap layer 164 has a first layer of InGaAs that may be doped at n⁺≈10¹⁹/cm³ and have a thickness of about 1000 Å and a second layer of AlInAs that may be doped at n⁺≈10¹⁹/cm³ and have a thickness of about 400 Å. As discussed above, the emitter layer 162 and the emitter ledge layer 150 may have a total thickness of 1000 Å. The emitter layer 162 comprising AlInAs would have a doping as discussed above, and the emitter ledge layer 150 comprising InP would have n≈5×10¹⁷/cm³. As discussed above, the thickness of the emitter ledge layer 150 should be less than the surface depletion depth in the fully depleted extrinsic region 154 of the emitter ledge layer 150. If a spacer layer is present between the emitter ledge layer 150 and the base layer 140, the spacer layer comprising InGaAs would have a doping of p≈2×10¹⁸/cm³ and a thickness of about 50 Å. The base layer 140 comprising InGaAs would have a doping of p⁺=3×10¹⁹/cm³ and a thickness of about 500 Å. The collector layer 130 comprising InGaAs would have a doping of n⁻≈5×10¹⁵/cm³ with a thickness of approximately 1000 Å to 3000 Å. The sub-collector layer 120 comprising InGaAs, InP, or a combination of InGaAs and InP, with a doping of n⁺≈2×10¹⁹/cm³, may have a thickness of approximately 3000 Å.

In an embodiment of the HBT 200 depicted in FIG. 4B, the emitter cap layer 264 has a first layer of InGaAs doped at n⁺≈10¹⁹/cm³ with a thickness of approximately 1000 Å and a second layer of InP doped at n≈10¹⁹/cm³ with a thickness of approximately 400 Å. The emitter layer 262, etch stop layer 266 and the emitter ledge layer 250 would have a total thickness of about 1000 Å. The emitter layer 262 comprising InP would be doped as discussed above. The etch stop layer 266 comprising Al_{0.24}Ga_{0.23}In_{0.53}As would be doped at n 5×10¹⁷/cm³ and would be approximately 50 Å thick. The rest of the structure of this embodiment of the HBT depicted in FIG. 4B would be similar to that described above for the embodiment of the HBT 100 depicted in FIG. 4A.

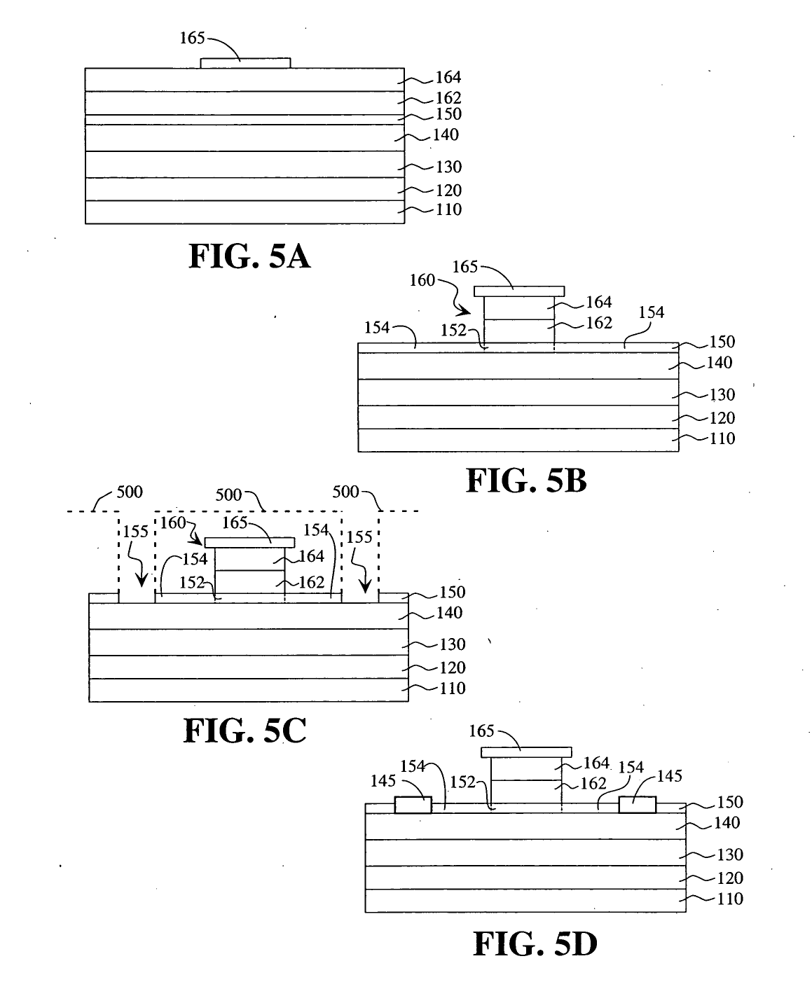

FIGS. 5A to 5D illustrate a process according to an embodiment of the present invention for fabricating the HBT 100 depicted in FIG. 4A. A similar process would be used to form the HBT 200 depicted in FIG. 4B. FIG. 5A illustrates the layers of the HBT 100 after the application of the emitter contact 165, but before the formation of the emitter mesa 160 (shown in FIG. 4A). As shown in FIG. 5A, the layers (from top down) comprise the emitter cap layer 164, the emitter layer 162, the emitter ledge layer 150, the base layer 140, the collector layer 130, the sub-collector layer 120, and the substrate layer 110. The emitter ledge layer 150 preferably completely covers the base layer 140.

FIG. 5B shows the semiconductor structure after the formation of the emitter mesa 160 (shown in FIG. 4A). The layers from the emitter cap layer 164 to the emitter layer 162 (immediately above the emitter edge layer 150) may be etched by a dry etch process, such as through the use of an Inductively Coupled Plasma (ICP) system with an end point to monitor optical emission signal strength, or a wet chemical selective etch using the emitter contact 165 as the mask. The etch stops at the top of the emitter ledge layer 150. If the semiconductor structure comprises the HBT 200 depicted in FIG. 4B, the etch may stop at the etch stop layer 266. A further etch would then be used to etch through the etch stop layer 266 to stop at the top of the emitter ledge layer 250.

FIG. 5C depicts the formation of gaps 155 in the emitter ledge layer 150 to receive the base contacts 145, which is preferably performed by photolithography. A photoresist 500 is applied to mask the emitter mesa 160 and those portions of the emitter ledge layer 150 not to be removed. Those portions of the emitter ledge layer 150 exposed by photolithography, i.e., the gaps 155, will be removed to expose the base layer 140. Preferably, removal of those portions of the emitter ledge layer is performed by ICP or wet chemical selective etch, thus leaving the gaps 155 in the emitter ledge layer 150. These gaps 155 will then receive the metal for the base contacts 145, as described below.

For a completely depleted extrinsic region 154 of the emitter ledge layer 150, the base contacts 145 may be brought as close to the edge of the emitter mesa 160 as 3000 Å by reducing the base contact recombination current. For additional description of this phenomena in GaAs-based HBTs, see W. Liu et al., “Parasitic Conduction Current in the Passivation Ledge of AlGaAs/GaAs Heterojunction Bipolar Transistors,” Solid State Electronics, Vol. 35, No. 7, 1992, pp. 891-895, and W. Liu et al., “Theoretical Comparison of Base Bulk Recombination Current and Surface Recombination Current of a Mesa AlGaAs/GaAs Heterojunction Bipolar Transistor,” Solid State Electronics, Vol. 34, No. 10, 1991, pp. 1119-1123. However, even with emitter ledge passivation to reduce base surface recombination current, the recombination current at the base contacts 145 may still limit the current gain of the HBT 100.

FIG. 5D depicts the structure after the metal for the base contacts 145 has been applied. The base contacts 145 are preferably formed by evaporation and lift-off, but other techniques known in the art may be used. As discussed above, the metal of the base contacts preferably comprises Pt/Ti/Pt/Au, but other metals or electrically conductive materials may be used. Preferably, the base contacts 145 are applied so that no portion of the base layer 140 is exposed. Therefore, no gaps should be present in the extrinsic region 154 of the emitter edge layer 150 so that 100% or nearly 100% passivation of the surface of the base layer 140 is provided. This also provides for protection of the base layer 140 in later processing of the HBT 100.

As indicated above, the extrinsic region 154 of the emitter ledge layer 150 essentially comprises a passivation ledge. There are various methods that can monitor passivation ledges. It is generally sufficient to compare the effective ratio of a long ledge device to a short ledge device. See, for example, P. J. Zampardi, et al., “Methods for Monitoring Passivation Ledges in a Manufacturing Environment,” GaAs Mantech Conference 2002, pp. 225-228. Similarly, beta ratio of a device with a longer ledge to a shorter ledge is a good parameter for ledge passivation evaluation. A ratio near 1 is expected for devices with a good ledge. Experiments comparing the base current ideality factor of HBTs with and without passivation, and with same emitter length but various emitter widths can also provide information of efficiency of surface passivation. See, for example, William Liu, Handbook of 11-V Heterojunction Bipolar Transistors, §3-6 Surface Current Ideality Factor, pp. 169-179.

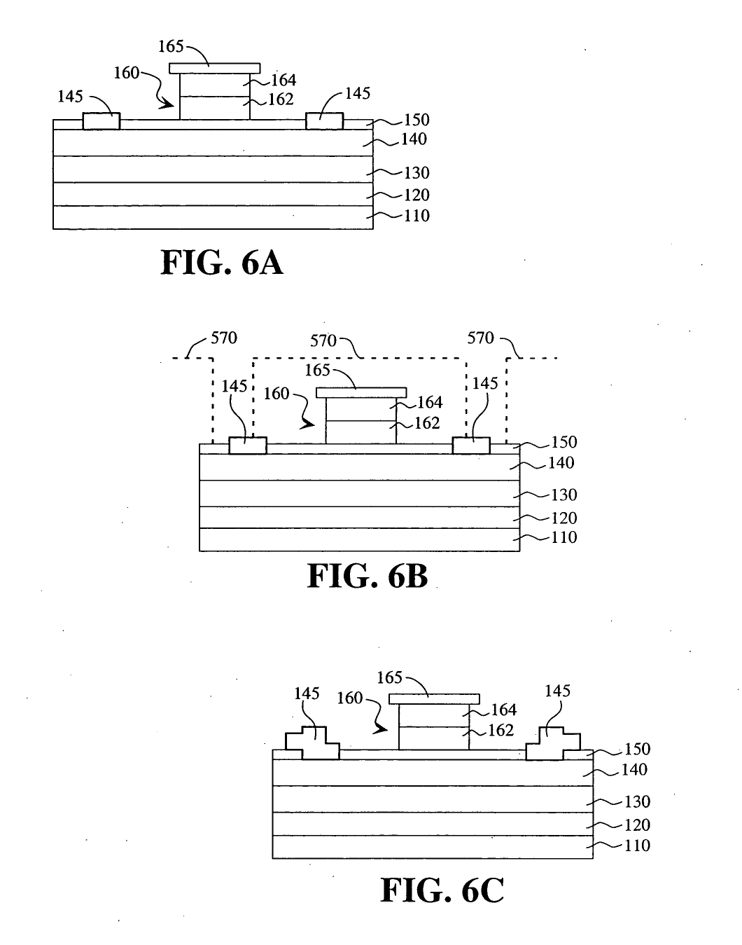

Additional processes may be used to obtain wider base contacts 145, 245 if needed. According to these processes, wider base contacts 145, 245 may be provided on at least one side of the emitter mesa 160, 260. Wider base contacts 145, 245 may be useful for a scaled HBT without increasing the extrinsic base-collector capacitance. One such additional process is depicted in FIGS. 6A to 6C.

FIG. 6A depicts the HBT 100 after the application of the base metal to form the base contacts 145 as previously shown in FIG. 5D. FIG. 6B shows the application of another photoresist mask 570 that masks the emitter mesa 160, adjacent portions of the emitter ledge layer 150, and portions of the base contacts 145. However, the photoresist mask 570 also exposes portions of the base contacts 145 and portions of the emitter ledge layer on the opposite side of the base contacts 145 from the emitter mesa. A second metalization step may then be performed to apply additional metal on top of the exposed portions of the base contacts 145 and the emitter ledge layer 150 as shown in FIG. 6C. As can be seen from FIG. 6C, the resulting base contacts 145 are wider than those depicted in FIG. 5D.

Due to the fully depleted emitter ledge as described above, embodiments of the present invention provide HBTs with reduced base surface recombination current, higher current gain, and lower base resistance than seen with other prior art devices. Since embodiments of the present invention provide that the external base surface is fully passivated and well protected from later processes, these embodiments should be more reliable than prior art devices.

From the foregoing description, it will be apparent that the present invention has a number of advantages, some of which have been described herein, and others of which are inherent in the embodiments of the invention described or claimed herein. Also, it will be understood that modifications can be made to the device and method described herein without departing from the teachings of subject matter described herein. Particularly, while embodiments of the present invention are described above in relation to the semiconductor structure of InP-based HBTs, other embodiments may relate to semiconductor structures other than those of InP-based HBTs. As such, the invention is not to be limited to the described embodiments except as required by the appended claims.

1. A semiconductor structure comprising:
an emitter mesa;
a base layer;
an emitter ledge layer located above the base layer and below the emitter mesa, the emitter ledge layer having an intrinsic region located beneath the emitter mesa and an extrinsic region located outside the intrinsic region, the extrinsic region comprising depleted semiconductor material; and
one or more base contacts formed within a portion of the extrinsic region of the emitter ledge layer and spaced at selected distances from the emitter mesa,
wherein the one or more base contacts electrically contact the base layer, and wherein the base contacts and the emitter ledge layer are disposed to cover an upper surface of the base layer so that there are no gaps in the emitter ledge layer between the one or more base contacts and the emitter mesa to leave the upper surface of the base layer exposed.

2. The semiconductor structure of claim 1, wherein the extrinsic region of the emitter ledge layer comprises fully depleted semiconductor material.

3. The semiconductor structure of claim 1, wherein the semiconductor structure comprises a portion of a heterojunction bipolar transistor (HBT).

4. The semiconductor structure of claim 3, wherein the HBT comprises an InP-based NPN HBT.

5. The semiconductor structure of claim 4, wherein the emitter mesa comprises: an emitter cap layer comprising layers of n⁺ InGaAs and n⁺ AlInAs, and an emitter layer comprising n⁻ AlInAs.

6. The semiconductor structure of claim 4, wherein the emitter mesa comprises:
an emitter cap layer comprising layers of n⁺ InGaAs and n⁺ InP;
an emitter layer comprising n⁻ InP; and,
an etch stop layer comprising AlGaInAs.

7. The semiconductor structure of claim 4, wherein the InP-based HBT comprises a single heterojunction bipolar transistor or a double heterojunction bipolar transistor.

8. The semiconductor structure of claim 1, wherein the emitter mesa is formed by etching down to the emitter ledge layer after an emitter contact is formed on the emitter mesa.

9. The semiconductor structure of claim 8, wherein one or more portions of the extrinsic region of the emitter ledge layer are etched down to the base region to open one or more areas for the one or more base contacts and the one or more base contacts are formed by depositing metal in the one or more areas.

10. The semiconductor structure of claim 9, wherein the one or more base contacts further comprise metal deposited on top of one or more portions of the emitter ledge layer, said metal deposited on top of the one or more portions of the emitter ledge layer in electrical contact with the metal deposited in the one or more areas.

11. The semiconductor structure of claim 1, wherein the extrinsic region of the emitter edge layer serves as a surface passivation layer for an upper surface of the base layer.

12. The semiconductor structure of claim 1, wherein the emitter ledge layer comprises n InP.

13. A method for fabricating a heterojunction bipolar transistor (HBT), comprising:
providing a substrate;
forming a collector layer and a base layer for the HBT on the substrate;
forming an emitter ledge layer above the base layer;
forming an emitter mesa region above the emitter ledge layer; and
forming one or more base contacts in the emitter ledge layer at selected distances from the emitter mesa, the one or more base contacts in electrical contact with the base layer,
wherein the emitter ledge layer has an intrinsic region located beneath the emitter mesa and an extrinsic region located outside the intrinsic region and the extrinsic region comprises depleted semiconductor material and wherein the one or more base contacts are formed in the extrinsic region and one or more base contacts and the emitter ledge layer are formed so that there are no gaps in the extrinsic region of the emitter ledge layer between the one or more base contacts and the emitter mesa to leave an upper surface of the base layer exposed.

14. The method of clam 13, wherein the extrinsic region comprises fully depleted semiconductor material.

15. The method of claim 13, wherein the HBT comprises an InP-based NPN HBT.

16. The method of claim 15, wherein the emitter mesa comprises:
an emitter cap layer comprising layers of n⁺ InGaAs and n⁺ AlInAs, and
an emitter layer comprising n⁻ AlInAs.

17. The method of claim 15, wherein the emitter mesa comprises:
an emitter cap layer comprising layers of n⁺ InGaAs and n⁺ InP;
an emitter layer comprising n⁻ InP; and
an etch stop layer comprising AlGaInAs.

18. The method of claim 15, wherein the InP-based HBT comprises a single heterojunction bipolar transistor or a double heterojunction bipolar transistor.

19. The method of claim 13, wherein the emitter mesa is formed by etching down to the emitter ledge layer after an emitter contact is formed.

20. The method of claim 19, further comprising:
applying a first patterned photoresist after the emitter mesa is formed and
using said first patterned photoresist mask to etch one or more portions of the extrinsic region of the emitter ledge layer down to the base layer to open one or more areas for the one or more base contacts.

21. The method of claim 20, further comprising forming base contacts by depositing metal in the one or more areas.

22. The method of claim 21, further comprising applying a second patterned photoresist to expose one or more areas for one or more expanded base contacts.

23. The method of claim 22, further comprising forming the one or more expanded base contacts by depositing metal in the exposed one or more areas.

24. The method of claim 13, wherein the extrinsic region of the emitter ledge layer serves as a surface passivation layer for an upper surface of the base layer.

25. The method of claim 13, wherein the emitter ledge layer comprises n⁻ InP.

26. A semiconductor structure comprising an InP-based NPN heterojunction bipolar transistor (HBT) wherein the InP-based NPN HBT has a fully depleted emitter ledge layer region disposed between one or more base contacts and an emitter mesa to 100% or nearly 100% passivate an upper surface of a base layer of the InP-based NPN HBT.

27. The semiconductor structure of claim 26, wherein the fully depleted emitter ledge layer region has no gaps in the emitter ledge layer between the one or more base contacts and the emitter mesa to leave an upper surface of the base layer exposed.
